(19) United States
(12) Patent Application Publication
(10) Pub. No.: US 2010/0043870 A1
(43) Pub. Date: Feb. 25, 2010

(54) SOLAR PANEL MONITORING SYSTEM

(76) Inventors: James D. Bennett, Hroznetin (CZ); Bruce E. Garlick, Austin, TX (US)

Correspondence Address: GARLICK HARRISON & MARKISON, P.O. BOX 160727, AUSTIN, TX, 78716-0727, US

(21) Appl. No.: 12/323,450

(22) Filed: Nov. 25, 2008

Related U.S. Application Data
(63) Continuation-in-part of application No. 12/197,720, filed on Aug. 25, 2008.

(51) Int. Cl. H01L 31/042

(52) U.S. Cl. 136/251

(57) ABSTRACT

A solar panel of a solar power generation system consisting housing within a roofing tile, photovoltaic panels and solar panel monitoring system disposed within the housing. The solar panel monitoring system, in turn, consists of solar panel processing circuitry, solar panel communications interface, solar panel memory and solar panel sensor coupled to the photovoltaic panel. The solar panel processing circuitry performs monitoring and maintenance activities within the roofing tile, by receiving sensory data from the solar panel sensor regarding performance of the photovoltaic panel and other modules and stores the received sensory data in the solar panel memory. In addition the solar panel processing circuitry is operable to deliver the stored sensory data to a central control unit via the solar panel communications interface. The other modules within the roofing tile includes solar panel communication and power interfaces, solar panel memory, heater assembly, electrical rotational assembly and lighting module, all of which are coupled to the photovoltaic panel via a solar panel power bus to receive power and interconnected via a solar panel communication bus.

### CROSS REFERENCES TO RELATED APPLICATIONS

The present application is a continuation-in-part and claims priority under 35 U.S.C. 120 to U.S. Utility Application Serial No 12/197,720, filed Aug. 25, 2008, which is incorporated herein by reference in its entirety for all purposes.

1. Technical Field

The present invention relates generally to electrical power generation and more particularly to photo voltaic electrical power generation.

2. Related Art

Today, most of the electrical power generated that is used to light and heat houses and buildings is derived from coal, petroleum, hydro electric dams, nuclear power, wind power, ocean current power and so forth. The electrical power is generated at power plants by utility companies and delivered to end users via transmission lines and distribution lines. The electrical power is distributed within homes and businesses at usable voltages. Power meters measure power consumed and a utility company bills the end user for such consumed power.

Most currently used techniques for generating electrical power have a fuel cost. All facilities for generating electrical power have a facility cost. Further, the cost of transmission and distribution lines is substantial. Power loss during transmission of the electrical power from the power plants to the end users can be substantial. As electrical power consumption continues to increase additional facilities must be constructed to service the increase in demand.

Fossil fuels, such as petroleum and coal that produce most electrical energy are non-renewable. The price of these natural resources continues to increase. In cases of hydro electric power generation, the available electric output depends entirely upon natural circumstances such as rain fall. For instance, during years when rainfall is low, power generation is also low, which affects the entire community who use this source of electrical power. Wind power is typically only available during daylight hours and fluctuates both seasonally and based upon local weather patterns. In the case of nuclear power, the technology is expensive, construction of power generating stations is expensive, and nuclear hazards cannot entirely be ruled out, in spite of extensive safeguards. Nuclear power generation is not available in many regions of the world because of security concerns.

In addition, adverse environmental effects from all of these power generation methods are enormous. In other words, each of these power generation methods has its own adverse environmental effects such as hydro electric dams adversely affecting bio-diversity and possibly causing floods of enormous destruction should a dam burst. Wind power generation takes huge amounts of land and may be aesthetically unpleasant. Coal and petroleum generation causes environmental degradation in the form of carbon dioxide and toxic emissions, causing enormous adverse effects on natural weather cycles, having damaging effects on life as a whole in the planet, in the long run. Similarly, nuclear waste can be hazardous; disposing them is very expensive and also has ability to have an adverse effect on the environment.

Moreover, with all of these above mentioned circumstances of power generation and environmental adverse affects, the average user's ability to contribute to improve the situation is next to nothing. So, the average consumer is helpless regarding these issues. Scientists for long have known that earth's only major renewable resource, as far as life is concerned, is the energy coming from the sun. These and other limitations and deficiencies associated with the related art may be more fully appreciated by those skilled in the art after comparing such related art with various aspects of the present invention as set forth herein with reference to the figures.

### BRIEF SUMMARY OF THE INVENTION

The present invention is directed to apparatus and methods of operation that are further described in the following Brief Description of the Drawings, the Detailed Description of the Invention, and the claims. Other features and advantages of the present invention will become apparent from the following detailed description of the invention made with reference to the accompanying drawings.

### BRIEF DESCRIPTION OF THE DRAWINGS

FIG. 1 is a perspective diagram with detail illustrating a solar panel of a solar power generation system constructed according to one or more embodiments of the present invention;

FIG. 2 is a block diagram illustrating an embodiment of a solar panel of the solar panel generation system of FIG. 1 constructed according to one or more embodiments of the present invention;

FIG. 3 is a schematic block illustrating another embodiment of a solar panel of the solar panel generation system of FIG. 1 constructed according to one or more embodiments of the present invention;

FIG. 4 is a schematic block illustrating another embodiment of a solar panel of the solar panel generation system of FIG. 1 constructed according to one or more embodiments of the present invention;

FIG. 5 is a schematic block illustrating another embodiment of a solar panel of the solar panel generation system of FIG. 1 constructed according to one or more embodiments of the present invention;

FIG. 6 is a schematic block illustrating another embodiment of a solar panel of the solar panel generating system of FIG. 1 constructed according to one or more embodiments of the present invention;

FIG. 7 is a schematic block illustrating an interconnection structure of the solar panel generation system of FIG. 1;

FIG. 8 is a flow diagram illustrating functionalities of the solar panel processing circuitry of the solar panel monitoring system of FIG. 1; and

FIG. 9 is a flow diagram illustrating functionalities of the solar panel processing circuitry of the solar panel monitoring system of FIG. 1; wherein the solar panel processing circuitry controls the functionalities of over load protection, heater assembly and electrical rotational assembly.

### DETAILED DESCRIPTION OF THE DRAWINGS

Generally, a solar power generation system includes a plurality of solar panels. Each solar panel includes a housing, a photovoltaic panel disposed within the housing, and a solar panel monitoring system that may be disposed within or external to the housing. The solar panel monitoring system includes solar panel processing circuitry, a solar panel communications interface, solar panel memory, and a solar panel sensor coupled to the photovoltaic panel. The solar panel processing circuitry is operable to receive sensory data from the solar panel sensor regarding performance of the photovoltaic panel and to store the received sensory data in the solar panel memory. The solar panel processing circuitry is operable to deliver the stored sensory data to a central control unit via the solar panel communications interface.

The solar panel may further include a solar panel power bus coupled to the photovoltaic panel and disposed within the housing and a power interconnection disposed upon an external portion of the housing and electrically coupled to the solar panel power bus. The solar panel power bus electrically couples to the solar panel monitoring system to power the solar panel monitoring system.

The solar panel communications interface may support wireless communications and/or wired communications via a wired communications port disposed on an external portion of the housing. The solar panel may further include a temperature sensor disposed within the housing, wherein the solar panel processing circuitry is operable to receive temperature data from the temperature sensor, to store the temperature data within the solar panel memory, and to deliver the stored temperature data to a central control unit via the solar panel communications interface. The solar panel monitoring system may include a packaged integrated circuit disposed within the housing and electrically connected to the photovoltaic panel.

The processing circuitry may deliver the stored sensory data to the central control unit via the solar panel communications interface upon demand from the central control unit. The processing circuitry may be operable to receive the sensory data over time, to determine that the photovoltaic panel requires maintenance based upon the sensory data received over time, and to deliver a maintenance request to the central control unit via the solar panel communications interface. The solar panel sensor may be a current sensor. The housing may include a transparent covering that protects the photovoltaic panel and the solar panel monitoring system. The solar panel may further include an interconnection structure disposed on an external portion of the housing for interconnection to at least one other solar panel. The interconnection structure disposed on an external portion of the housing may be for interconnection to a solar panel generation system interconnection structure.

The solar panel monitoring system may include a light sensor. The solar panel may further include an electrical rotational assembly upon which the photovoltaic panel mounts and that is operational to position the photovoltaic panel for enhanced power generation. The solar panel may further include a heater operable to heat a surface of the housing to melt accumulated snow.

Embodiments of the present invention further include a method for operating a solar panel of a solar power generation system that includes a housing, a photovoltaic panel disposed within the housing, and a solar panel monitoring system disposed within the housing that includes solar panel processing circuitry, a solar panel communications interface, solar panel memory, and a solar panel sensor coupled to the photovoltaic panel. The method includes receiving sensory data from the solar panel sensor regarding performance of the photovoltaic panel, storing the received sensory data in the solar panel memory, and delivering the stored sensory data to a central control unit via the solar panel communications interface.

The method may further include coupling electrical power generated by the photovoltaic panel to an external portion of the housing via a solar panel power bus coupled to the photovoltaic panel and disposed within the housing. The method may also/alternately include powering the solar panel monitoring system via the solar panel power bus. The method may also/alternately include delivering the stored sensory data to the central control unit via the solar panel communications interface by wirelessly communicating via the solar panel communications interface. The method may also/alternately include delivering the stored sensory data to the central control unit via the solar panel communications interface by communicating via a wired communications port disposed on an external portion of the housing.

The method may also/alternately include receiving temperature data regarding temperatures within the housing via a temperature sensor, storing the temperature data within the solar panel memory, and delivering the stored temperature data to a central control unit via the solar panel communications interface. The method may also/alternately include delivering the stored sensory data to the central control unit via the solar panel communications interface in response to a request received from the central control unit.

The method may also/alternately include receiving the sensory data over time, determining that the photovoltaic panel requires maintenance based upon the sensory data received over time, and delivering a maintenance request to the central control unit via the solar panel communications interface. The method may also/alternately include receiving sensory data from the solar panel sensor regarding performance of the photovoltaic panel by receiving current generation data regarding the photovoltaic panel. The method may also/alternately include positioning the photovoltaic panel for enhanced power generation. The method may also/alternately include heating at least one of the photovoltaic panel and the housing to melt accumulated snow.

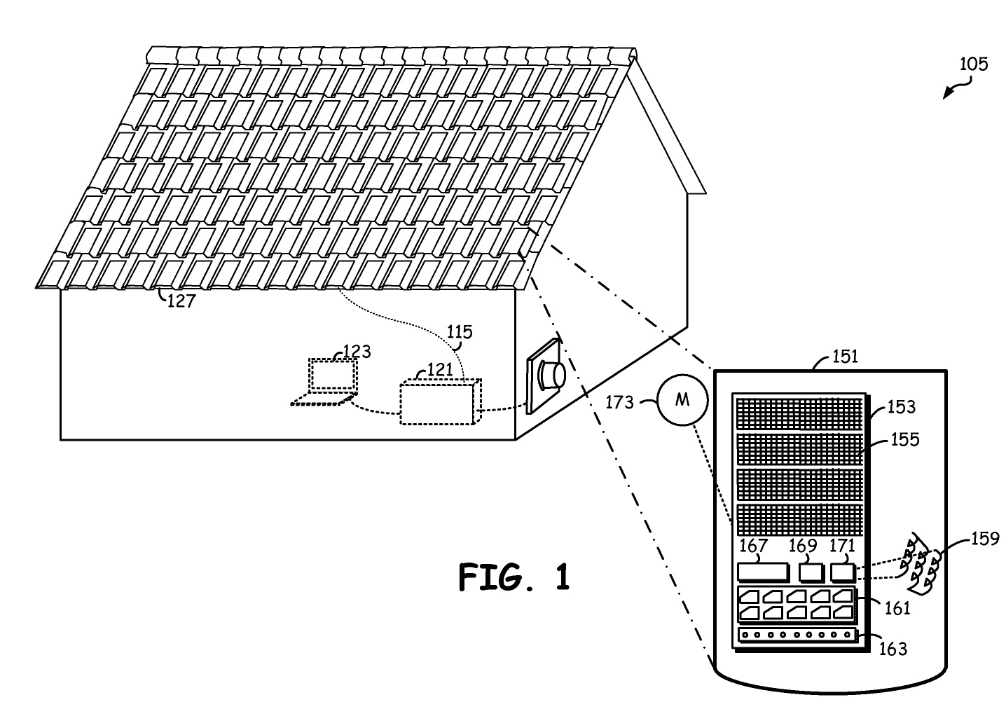

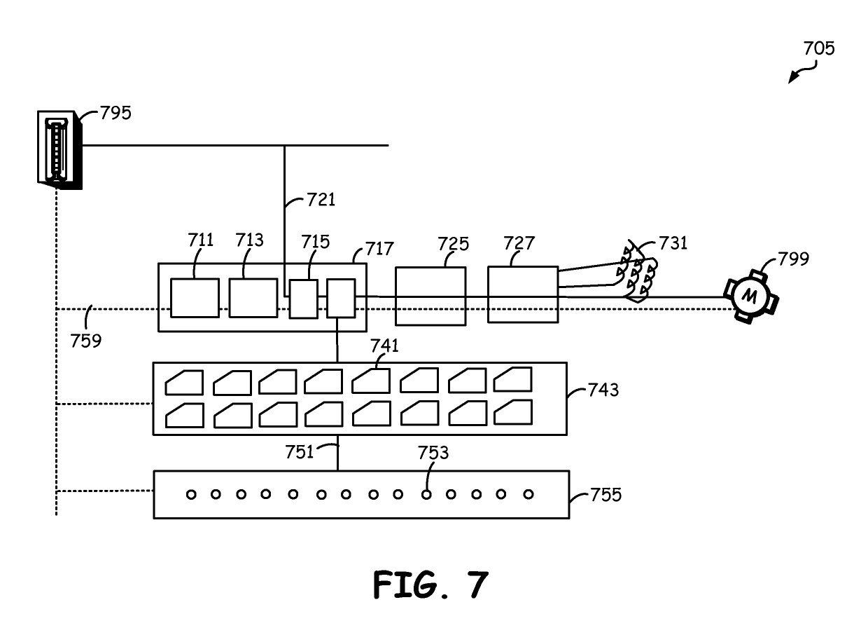

FIG. 1 is a schematic block diagram illustrating a solar panel 153 of a solar power generation system 105, wherein the roofing tile 127 consists of a housing 151 to receive solar panel consisting photovoltaic panel 155 and a solar panel monitoring system 161, 163, 167, 169 and 171, in accordance with the present invention. In specific, the housing (cavity or docking system) 151 consists of photovoltaic panel 155 and solar panel monitoring system 161, 163, 167, 169 and 171; which in turn consists of modules such as a solar panel processing circuitry module 167, overload and fire response system module 169, sensor module 161, electrical rotational assembly 173, heater assembly 171, 159 and status indicator and decoration lighting module (lighting module, hereafter) 163, in accordance with the present invention. The solar panel processing circuitry module 167 in turn consists of a solar panel processing circuitry, solar panel power and communications interfaces and solar panel memory (not shown, refer to the FIG. 7 for detailed description). All of these modules 161, 163, 167, 169 and 171 of the solar panel monitoring system are coupled to the photovoltaic panel 155, via a solar panel power bus driver, solar panel power bus and solar panel power interface, for deriving power.

In specific, all these components of the solar panel (photovoltaic panel 155, solar panel monitoring system such as the solar panel processing circuitry module 167, overload and fire response system module 169, sensor module 161, heater module 171 and lighting module 163) and modules within the cavity such as the electrical rotational assembly (or solar panel azimuth and altitude control motors or hydraulic systems and interfaces) 173 and heater coils 159 are termed here as solar panel modules (that exist within each of the roofing tiles such as 127).

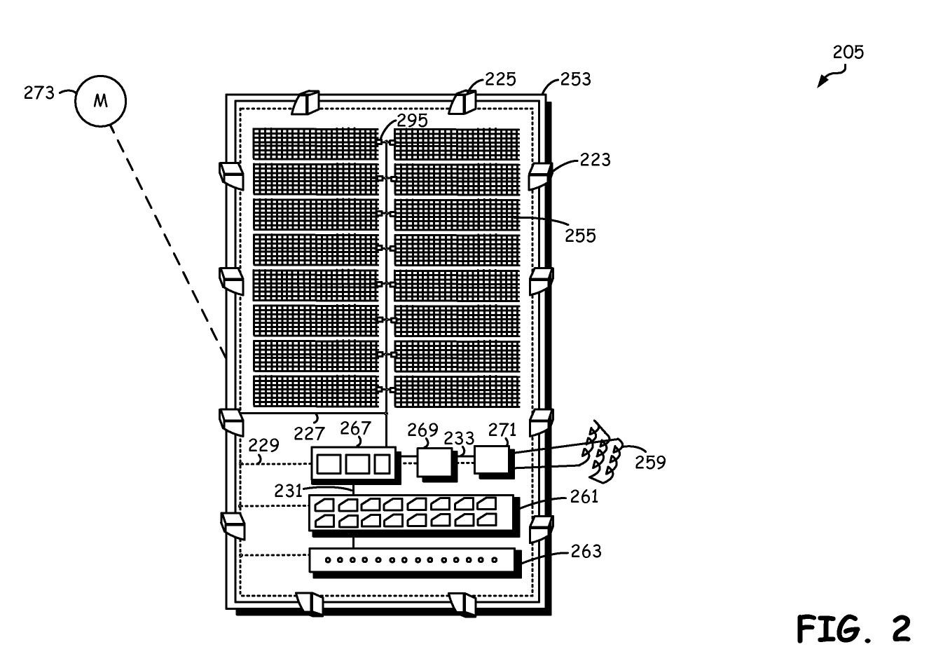

The solar panel modules 159, 161, 163, 167, 169, 171 and 173 are powered by solar panel power bus driver, solar panel power buses (not shown here, refer to the FIGS. 2 through 5 for detailed description), either directly, via respective interfaces (or drivers) or via solar panel power interface (built into the solar panel processing circuitry module 167—again, refer to the FIGS. 2 through 5 for detailed description). Similarly, the solar panel modules 161, 163, 167, 169, 171 and 173 are controlled via solar panel communication buses (not shown here, refer to the FIGS. 2 through 5 for detailed description), either directly, via respective communication interfaces, or via solar panel communication interface (built into the solar panel processing circuitry module 167—again, refer to the FIGS. 2 through 5 for detailed description). The solar panel power buses and solar panel communication buses may run along the solar panel 153 on the side where solar panel modules 155, 159, 161, 163, 167, 169 and 171 are mounted or on the backside of the solar panel 153. Some of these solar panel power buses and solar panel communication buses may extend beyond the solar panel 153, by way of external wires and parallel buses, when some of the solar panel modules (such as some part of the sensors 161, some part of the lighting modules 163, electrical rotational assembly 173 or heater coils 159) cannot be mounted on the solar panel 153 because of their functionalities.

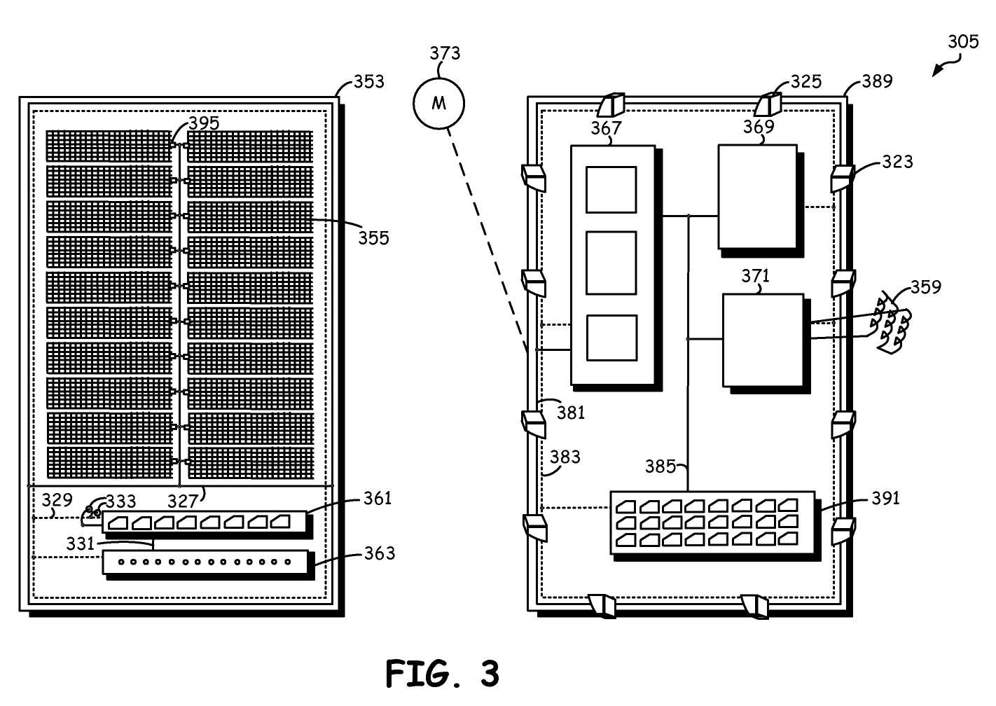

In one of the simpler embodiments of the present invention, the solar panel 153, installed in some of the tiles, may contain bare minimum components; that of one or more photovoltaic panel 155 and corresponding solar panel bus drivers (refer to the FIGS. 2, 3, 4 and 5). In this case, the solar panel 153 contains a solar panel power bus that at one end couples to each of the photovoltaic panel 155 (via the corresponding solar panel bus drivers) and at other end connects electrically (secures the solar panel 153 mechanically, within the housing 151) to one or more or solar panel power ports (refer to the FIGS. 2 and 3, for instance). The solar panel power ports, during placing of the solar panel 153 in the housing 151 of the roofing tile such as 127, get attached to corresponding housing power ports that leads to the neighboring roofing tiles, to form a first panel array power bus. The first panel array power bus 115 finally leads to a central control unit 121. Alternatively, the housing power ports may also electrically connect to wiring along battens that support the roofing tiles such as 127, to form a second panel array power bus. The second panel array power bus 115 also, (as a stand alone panel array power bus without the first panel array power bus 115 or in parallel to the first panel array power bus 115, for longevity), lead to the central control unit 121.

In a second embodiment of the present invention (the solar panel 153 that are installed in one of a block of the tiles, for instance), in addition to the solar panel power bus, first and/or second panel array power buses, solar panel power ports and housing power ports, the solar panel 153 within the roofing tile such as 127 may also carry solar panel communication buses, first and/or second panel array communication buses (similar to the first and/or second panel array power buses), solar panel communication ports and housing communication ports. These communication buses, solar panel communication ports and housing communication ports on the solar panel 153 (within the roofing tile 127) may exist only when there is at least one more element of solar panel monitoring system 159, 161, 163, 167, 169, 171 and/or 173 present. In addition, the solar panel communication ports and housing communication ports may exist separately as individual ports (without being clubbed with the corresponding solar panel power ports and outlets as single units) at appropriate locations on the solar panel 153 and roofing tile 127 or may exist as a single unit with the corresponding solar panel power ports, housing power ports, solar panel communication ports and housing communication ports.

The solar panel 153, in this case, contains at least one solar panel communication bus that at one end communicatively couples to some of the solar panel modules 161, 163, 167, 169, 171 and 173 (via corresponding interfaces) and at other end communicatively couples to one or more of solar panel communication ports and outlets. During docking of the solar panel 153 in the housing of the roofing tile 127, the solar panel communication ports get attached to housing communication ports, in corresponding places. The housing communication ports in turn are communicatively coupled to at least one housing communication ports of each of neighboring roofing tiles, to form a first panel array communication bus. This first panel array communication bus 115 ultimately leads to the central control unit 121. Alternatively, the housing communication ports may also communicatively couple to outlets of each of neighboring roofing tiles, via wiring along battens that support the roofing tiles such as 127, to form a second panel array communication bus. The second panel array communication bus 115 may also, in parallel, lead to the central control unit 121, to form an only panel array communication bus or a redundant panel array. Alternatively, the solar panel communication ports may contain wireless communication interfaces that communicatively couple to the central control unit 121 directly.

These solar panel modules 155, 159, 161, 163, 167, 169, 171 and 173, some of which are optional, provide a variety of monitoring and maintenance functionality to the solar power generation system 105, but each of the additional functionalities may come at an extra cost. The user is able to determine the functionality to be incorporated at various places within the roofing. For example, the lighting module 163 may contain a plurality of bulbs (such as LEDs) that indicate either functional status of different solar panel modules (such as various photovoltaic panels 155, solar panel processing circuitry module 167, overload and fire response systems 169, sensor modules 161, electrical rotational assembly 173, heater modules 171 and lighting modules 163) as well as decorating the house by lighting in multitude of ways. The status indicator bulbs of the lighting module 163 may be made functional from a central control unit 121 (located accessibly within house), and be made to function when needed (for instance, it may display a green light for a proper functioning and red light for a non-functional solar panel module systems). On the contrary, the decoration bulbs (which may exist only in some roofing tiles that are used as roofing edge tiles, for instance) may also be switched on from the central control unit 121, may be used on the edge tiles to decorate the house during any celebrations (festivals, parties or ceremonies, for instance); but may not contain any other functionality associated with them. Similarly, heater coils 159 may be powered on by the corresponding heater module 171 in conjunction with the central control unit 121, either automatically (based upon sensor data from the sensor module 161) or manually (via a computing system 123), and so forth.

For example, a home user who is interested in employing solar power generation system 105 may decide upon various tile schemes to various locations of the roofing, depending upon cost estimations. They may include one or more of: a simple roofing tile 127 scheme with only solar panels, solar panel power buses, panel array power buses 115, solar panel power ports and housing power ports on each of the solar panel 153 and roofing tile 127; and in addition to the above, a variety of combinations of solar panel modules such as 167, 169, 171, 161, 163, 159 and/or 173, solar panel communication buses, first/second panel array communication buses 115, solar panel communication ports and housing communication ports on each of the solar panel 153 within some of the roofing tiles.

For example, at the edges of roofing (such as the tile 127, for instance), the user may determine to install tiles with decoration lighting, in the middle regions of the roofing, the user may decide to install few tiles that contain solar panel monitoring system with all of the solar panel modules 155, 159, 161, 163, 167, 169, 171 and 173 in one tile for a block of tiles (that monitors, maintains and controls the functionalities of the entire block of tiles), while the rest of the tiles within that block may contain bare minimum of the solar panel modules (such as solar panels 155, solar panel power buses and communication buses, first/second panel array power buses and communication buses, solar panel power and communication ports in a single unit, housing power and communication port in a single unit, solar panel processing circuitry module 167, overload and fire response system module 169 and only few lighting module 163), and so forth.

With the embodiment of FIG. 1, the solar panels 151 are shown to be installed within cavities of tiles disposed on a roof. In other embodiments, the solar panels 151 are components of a system that includes a mounting structure that is not part of roofing tiles. In such embodiments, the solar panels 151 may be mounted upon a support structure that couples to a roof. This support structure may include a power bus system and a communication bus system in addition to its supporting structure. The supporting structure may include movable supports that allow the solar panels 151 to be oriented in a selected direction to enhance solar collection characteristics.

FIG. 2 is a schematic block illustrating construction of solar panel monitoring system of FIG. 1; wherein the solar panel monitoring system consists of a solar panel processing circuitry module (consisting a solar panel processing circuitry, solar panel communication and power interfaces, solar panel memory) 267, heater assembly 271, 259, sensor module 261, lighting module 263, all of which are coupled to photovoltaic panels 255 via a solar panel power bus 227 to receive power and interconnected via a solar panel communication bus 229, in accordance with an embodiment of the present invention. In specific, the photovoltaic panels 255, via corresponding solar panel bus drivers 295 (and the solar panel power bus 227, panel array power buses, solar panel power ports 223, 225, housing power ports, housing power ports and outlets on the solar panel 253 and within the roofing tile such as the 127 of FIG. 1) deliver power to a central control unit (121 of FIG. 1).

In a first embodiment of the present invention, the modules present on the solar panel 253 and within the roofing tile (such as sensor module 261, electrical rotational assembly 273 that makes azimuth and altitude rotations via hydraulic/stepper/motor positional control units possible, heater assembly 271, 259 and lighting module 263) derive power from the solar panel power bus 227 as well. This is done by solar panel processing circuitry module's 267 power driver/interface module, that is electrically connected to the solar panel power bus 227, generating an industry standard voltage (such as 5 volts and 12 volts) for each of the modules to function appropriately. For example, most solar panel modules such as the solar panel processing circuitry, sensor module 261 and lighting module 263 may be driven by 5 volts power supply, while other solar panel modules such as the electrical rotational assembly 273 and heater assembly 271, 259 may be driven by 12 volts.

The power from the solar panel processing circuitry module's 267 power driver/interface module are supplied via a second solar panel power bus 231 and/or third solar panel power bus 233 and so forth. This allows the solar panel processing circuitry (within the module 267) to shut off any of the module present on the solar panel 253 and within the roofing tile (such as photovoltaic panels 255, sensor module 261, electrical rotational assembly 273, heater assembly 271, 259 and lighting module 263), when there is malfunctioning or fire hazards. In this embodiment, however, an exclusive overload and fire response system module 269 may not exist; alternatively, the overload and fire response system module 269 may send feedback control signals to the solar panel processing circuitry module 267 to take appropriate action, during hazardous situations such as overloading, smoke, excessive humidity, excessive heating in any module and fire within the roofing tiles (due to lightning, for instance).

In addition, the modules present on the solar panel 253 and within the roofing tile (such as overload and fire response system module 269, sensor module 261, electrical rotational assembly 273, heater assembly 271, 259 and lighting module 263) communicate with the solar panel processing circuitry module 267 and the central control unit via the solar panel communication bus 229. The central control unit is communicatively coupled to the solar panel processing circuitry module 267 and rest of the modules on the solar panel 253 and within the roofing tile via the solar panel communication buses 229, first/second panel array communication buses (refer to the description of the FIG. 1), solar panel communication ports 223, 225, housing communication ports and outlets.

In a second embodiment, each of the modules present on the solar panel 253 and within the roofing tile such as the solar panel processing circuitry module 267, overload and fire response system module 269, sensor module 261, electrical rotational assembly 273, heater assembly 271, 259 and lighting module 263 are powered directly from the solar panel power bus 227, via their own corresponding power driver/interface modules (built into the corresponding modules themselves).

FIG. 3 is a schematic block illustrating construction of solar panel monitoring system of FIG. 1 (in two parallel boards to enhance solar power capturing); wherein the solar panel monitoring system consists of a solar panel processing circuitry module (consisting a solar panel processing circuitry, solar panel communication and power interfaces, solar panel memory) 367, heater assembly 371, 359, sensor modules 361, 391 and lighting modules 363, all of which are distributed in two boards 353 and 389, and are coupled to photovoltaic panels 355 via solar panel power drivers 395 and solar panel power buses 327, 385 to receive power and interconnected via a solar panel communication buses 329, 383.

In this embodiment of the present invention, the solar panel modules are distributed between the top and bottom solar panels 353 and 389 to maximize the solar power capturing. In other words, the top solar panel 353 contains all of the photovoltaic panels 355 and resides on top of the bottom solar panel 389, within housing of the roofing tile. In addition, only bare minimum solar panel modules are present on the top solar panel 353 (only those modules that by their functionalities cannot be mounted on the bottom solar panel 389), besides the photovoltaic panels 355. For example, some of the sensor modules 361 (such as light sensors that should be exposed to external light) and lighting module 363 (that should be visible externally) may be placed on the top solar panel 353, while rest of the solar panel modules such as solar panel processing circuitry module 367, overload and fire response system module 369, rest of the sensor modules 391, heater module 371, and solar panel power and communication ports 323, 325 maybe placed on the bottom solar panel 389. The electrical rotational assembly 373 is placed on the backside the solar panel 389. The top and bottom solar panels 353 and 383 are interconnected via the solar panel power bus and solar panel communication bus connections 333.

The photovoltaic panels 355 are connected to the solar panel power bus 327 via the solar panel bus drivers 395, which in turn are electrically coupled to a central control unit via the solar panel power buses 327, 381, first/second panel array power buses (refer to the FIG. 1 for more description), solar panel power ports 323 and 325, housing power ports and outlets on the bottom solar panel 389 and within the roofing tile. The solar panel modules present on the top solar panel 353, bottom solar panel 389 and within the roofing tile (such as the solar panel processing circuitry module 367, overload and fire response system module 369, sensor modules 361, 391, electrical rotational assembly 373, heater assembly 371, 359 and lighting module 363) derive power from the solar panel processing circuitry module's 367 power driver/interface module via secondary solar panel power busses such as 331 and 385. The solar panel processing circuitry module's 367 power driver/interface module in turn derives power from the solar panel power bus 327 and 381. Alternatively, each of the modules present on the top and bottom solar panels 353 and 389 and within the roofing tile may be powered directly from the solar panel power buses 327 and 381, via their own corresponding power driver/interface modules (built into the corresponding modules themselves).

In addition, the modules present on the top and bottom solar panels 353 and 389 and within the roofing tile communicate with the solar panel processing circuitry module 367 and the central control unit via solar panel communication buses 329 and 383. The central control unit is communicatively coupled to the solar panel processing circuitry module 367 and rest of the modules on the top and bottom solar panels 353, 389 and within the roofing tile via the solar panel communication buses 329 and 383, first/second panel array communication buses (refer to the FIG. 1 for more description), solar panel communication ports 323 and 325, housing communication ports and outlets.

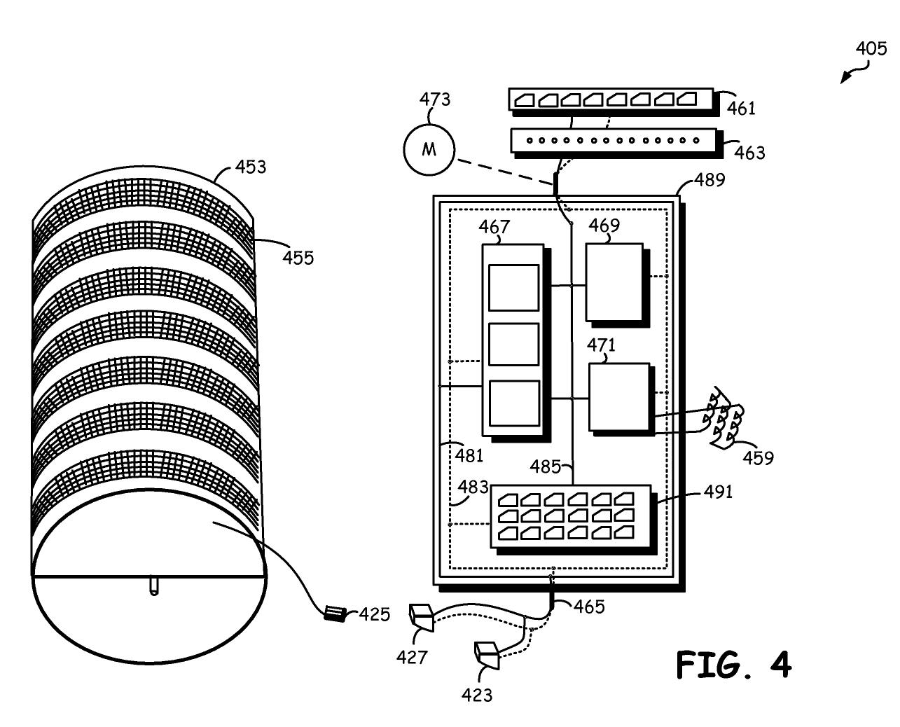

FIG. 4 is a schematic block illustrating construction of solar panel monitoring system (in cylindrical shaped board 453 and central board 489, to enhance solar power capturing and self cleaning) of FIG. 1; wherein the solar panel monitoring system consists of a solar panel processing circuitry module (consisting a solar panel processing circuitry, solar panel communication and power interfaces, solar panel memory) 467, heater assembly 471, 459, sensor modules 461, 491 and lighting modules 463, all of which are distributed between the cylindrical shaped board 453 and central board 489 (and/or placed externally, within the housing), and are coupled to the photovoltaic panels 455 via a solar panel power bus 485 to receive power and interconnected via a solar panel communication bus 483.

The solar panel 489 stays at the center of the cylinder (fixed by sliding into a slot at the center of the cylinder 453). The cylindrical photovoltaic panels 455 are connected to the solar panel power bus 481 via solar panel power ports 425, 427 and solar panel bus drivers (not shown). The solar panel power bus 481, in turn, is connected to a central control unit via first/second panel array power buses (refer to the FIG. 1 for more description), solar panel power ports 423, housing power ports and outlets within the roofing tile. The solar panel power bus 481, either directly or via secondary solar panel power buses 485 (and via the solar panel processing circuitry module's 467 power driver/interface module) deliver power to other solar panel modules such as overload and fire response system module 469, sensor modules 461, 491, self-cleaning rotational system 465, 473, heater module 471 and lighting module 463. The self-cleaning functionality is performed by rotating the solar panel 453 (and the cylindrical photovoltaic panels 455) periodically against brushes installed within the cavity of the roofing tiles.

Similarly, the central control unit communicates with the solar panel processing circuitry module 467 (and other solar panel modules 461, 463, 469, 471, 473 and 491) via solar panel communication buses 483, first/second panel array communication buses (refer to the FIG. 1 for more description), solar panel communication ports 423, housing communication ports and outlets within the roofing tile. The solar panel processing circuitry module 467 has its own communication interface to handle these communications. In addition, the solar panel processing circuitry module 467 communicates with other solar panel modules such as overload and fire response system module 469, sensor modules 461, 491, self-cleaning rotational system 465, 473, heater module 471 and lighting module 463, via solar panel communication buses 483. The individual solar panel modules 461, 463, 469, 471, 473 and 491 have their own communication interfaces that make communication possible. In addition, some of the modules that cannot be mounted on the solar panel 489, such as lighting module 463, heating elements 459 and sensor modules 461, because of their functionalities, are mounted separately within the roofing tiles.

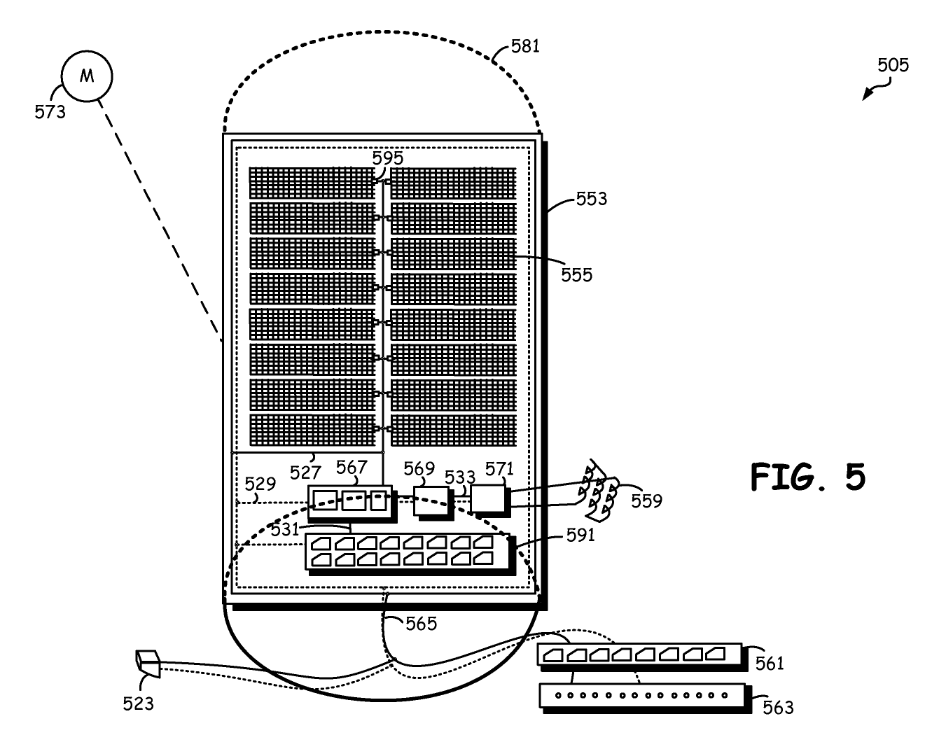

FIG. 5 is a schematic block illustrating construction of solar panel monitoring system (within a glass cylinder 581 and a solar panel 553 at the center) of FIG. 1; wherein the solar panel monitoring system consists of a solar panel processing circuitry module (consisting a solar panel processing circuitry, solar panel communication and power interfaces, solar panel memory) 567, heater assembly 571, 559, sensor modules 591, 563 and lighting modules 563, all of which are placed in the central board 553, and are coupled to the photovoltaic panels 555 via a solar panel power bus 527 to receive power and interconnected via a solar panel communication bus 529.

In this embodiment of the present invention, the solar panel 553 containing pluralities of solar panel modules such as photovoltaic panels 555, solar panel processing circuitry module 567, overload and fire response system module 569, sensor modules 561, 591 self-cleaning rotational system 565, 573, heater module 571, lighting module 563, solar panel power buses 527, 531, 533, solar panel communication bus 529 and solar panel power and communication ports 523 are housed within a glass cylinder 581 (slid into a slot at the center of the cylinder 581). This allows self-cleaning of the glass cylinder 581. In other words, periodic rotations of the glass cylinder 581 against a brush (not shown) incorporated within the roofing tiles allow self-cleaning of the cylinder 581.

In addition, some of the components that cannot be mounted on the solar panel 553 (because of their functionalities, such as some sensors 561, heating elements 559 and lighting module 563), are mounted separately within the roofing tiles. In an alternative embodiment, the solar panel modules such as 555, 567, 569, 591, 571, 561 and 563 may also be distributed into two parallel solar panels (similar to the ones in FIG. 3), so as to enhance capturing of solar power, while keeping the self-cleaning functionality of the cylinder 581 intact.

In this embodiment, similar to the embodiments of FIGS. 2, 3 and 4, the photovoltaic panels 555 generate electrical power, which is delivered to a central control unit via solar panel bus drivers 595, solar panel power bus 527, first/second panel array power buses (refer to the FIG. 1 for more description), solar panel power ports 523, housing power ports and outlets within the roofing tile. In addition, the solar panel modules such as 567, 569, 561, 591, 573, 559, 569, 571 and 563 derive power directly from the solar panel power bus 527 via their own built-in power interfaces/drivers or derive power via the interface/driver of the solar panel processing circuitry module 567 from the secondary solar panel power busses 531 and 533. In addition, the solar panel modules such as 569, 561, 591, 573, 559, 569, 571 and 563 communicate with the central control unit or solar panel processing circuitry module 567, using their own built-in communication interfaces, via solar panel communication bus 529, solar panel communication ports 523, housing communication ports and outlets within the roofing tile.

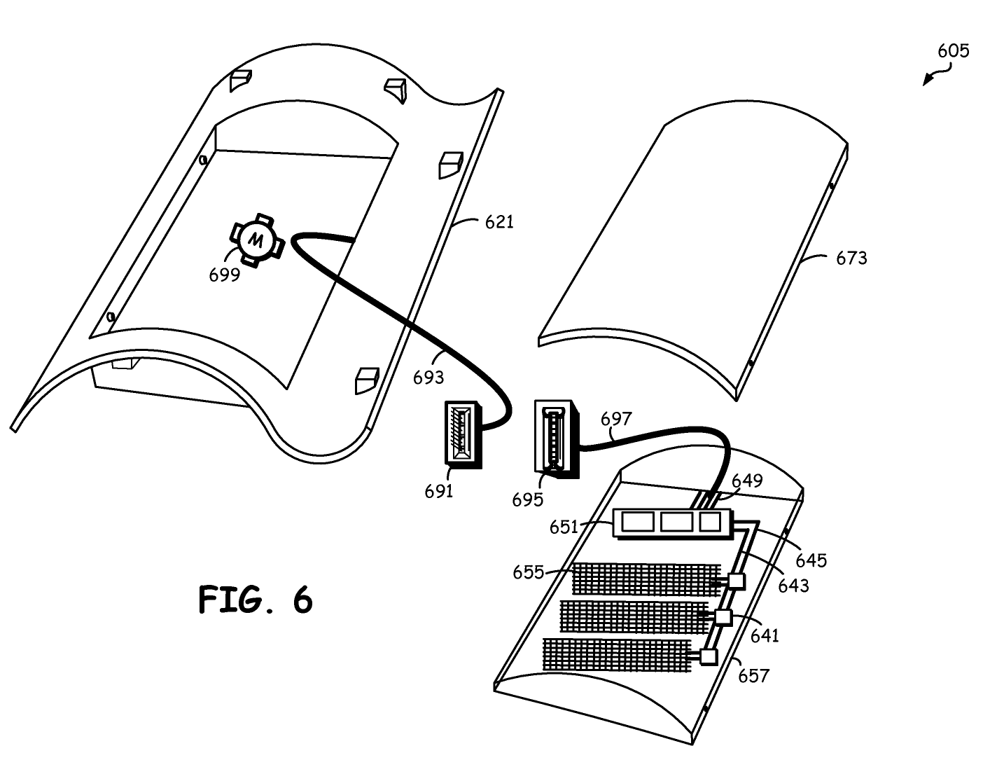

FIG. 6 is a schematic block illustrating construction of solar panel monitoring system of FIG. 1; wherein the solar panel monitoring system also consists of an electrical rotational assembly 699 that is operational to position the solar (photovoltaic) panel for enhanced power generation, in accordance with an embodiment of the present invention. The illustration also depicts some elements of the solar panel monitoring system such as solar panel processing circuitry module (consisting a solar panel processing circuitry, solar panel communication and power interfaces, solar panel memory) 651, while other elements are not depicted here (refer to the FIGS. 2 through 5 for detailed description of these elements).

Typically, the electrical rotational assembly 699 is mounted on the front face of roofing tile 621 (that is, within the housing) and may consist of solar panel azimuth and altitude controlling motors, steppers or hydraulic systems and interfaces. The electrical rotational assembly 699 is capable of making stepwise or continuous motion or shift from its original position, in any direction to a certain degree (that depends upon the sun movement in the sky above). The stepwise or continuous motion that the electrical rotational assembly 699 makes is controlled by one of: (i) Preprogrammed firmware embedded within the electrical rotational assembly 699, performed via a processor and memory, and controlled so as to face the direction of solar light or maximum available light, based upon knowledge of the daily and seasonal sun movements or feedback from a light sensor placed within solar panel 657 or elsewhere within a block of roofing tiles 621; (ii) Preprogrammed firmware embedded within the solar panel processing circuitry module 651 and controlled so as to face the direction of solar light and current or maximum available light, based upon knowledge of the daily and seasonal sun movements or feedback from a light sensor placed within solar panel 657 or elsewhere within a block of roofing tiles 621; and/or (iii) Program directed at the solar panel processing circuitry module 651 or the electrical rotational assembly 699 (within the corresponding roofing tiles such as 621), by a central control unit, and controlled either manually, remotely by a server (connected via Internet) or an preinstalled software program, so as to face the direction of maximum available light (based upon knowledge of the daily and seasonal sun movements or feedback from a light and current sensor placed within solar panel 657, elsewhere within a block of roofing tiles 621, within solar power generation system or within the locality.

The detachable solar panel 657 that docks into the housing of the roofing tile 621, sits on the top of the electrical rotational assembly 699 in such a way as to allow the slight rotational motion of shift towards the direction of maximum light possible. The electrical rotational assembly 699 is electrically and communicatively coupled to the detachable solar panel 657 via a wirings and connections 697, 695, 693 and 691, so as to be able to detach the solar panel 657 (should any need for maintenance arise).

Alternatively, the electrical rotational assembly 699 may also be placed at the bottom side of the solar panel 657. Other elements depicted in the illustration include photovoltaic panels 655, solar panel bus drivers 641, solar panel power bus 643, solar panel communication bus 645, solar panel ports 649 and solar panel external covering 673.

FIG. 7 is a schematic block illustrating interconnection structure of the solar panel monitoring system of FIG. 1; wherein the solar panel monitoring system consists of a solar panel processing circuitry 711, solar panel communication and power interfaces 715, 717, solar panel memory 713, heater assembly 727, 731, sensor module 743, electrical rotational assembly 799 and lighting module 755, all of which are coupled to the photovoltaic panel via a solar panel power bus 721 to receive power and interconnected via a solar panel communication bus 759, in accordance with an embodiment of the present invention.

At the center of the solar panel monitoring system lies in the solar panel processing circuitry module 717 that contains the solar panel processing circuitry 711, solar panel communication and power interfaces 715, 717 and solar panel memory 713. The solar panel processing circuitry module 717 is communicatively coupled to a central control unit, and powered by the photovoltaic panels via the solar panel bus drivers and solar panel power bus 721. The solar panel processing circuitry 711 controls all of the functionalities of the solar panel monitoring system, based upon the: (i) Preinstalled program stored in the solar panel memory 713; and/or (ii) Program received from the central control unit and stored in the solar panel memory 713, at any later time, after the installation. The solar panel communication and power interfaces 715, 717 deliver the power for all of the modules 711, 713, 715, 717, 725, 727, 731, 743 and 755 within the roofing tile and make communication between the solar panel processing circuitry 711 and rest of the modules 713, 715, 717, 725, 727, 743, 755 and central control unit possible.

The functionalities that are controlled by the solar panel processing circuitry 711 include functionalities of the overload and fire response module 725, heater assembly 727, 731, sensor module 743, electrical rotational assembly 799 and lighting module 755. The functionality of sensor module 743 (containing sensors 741 such as light, temperature, current, humidity, and so forth) includes gathering the sensor readings periodically and storing them in the solar panel memory 713. The functionality of heater assembly 727, 731 may simply involve switching it on or off based upon temperature sensor and light sensor readings, or based upon control inputs from the central control unit. The functionality of the electrical rotational assembly 799 includes rotating the direction of the solar panel based upon the sensor readings of current or light, or alternatively, based upon control inputs from the central control unit. The light module 755 (consisting many lights 753, such as LEDs) functionality includes displaying externally visible status indications of various functionalities such as functioning of the overload and fire response module 725, sensor module 743, heating assembly 727, 731, photovoltaic panels and so forth. The light module 755 functionality may be remotely, from the central control unit for instance, switched on and off, to minimize power wastage.

The solar panel power bus 721 and solar panel communication bus 759 are electrically and communicatively coupled to the neighboring tiles and central control unit via a connection port 795 built into the solar panel.

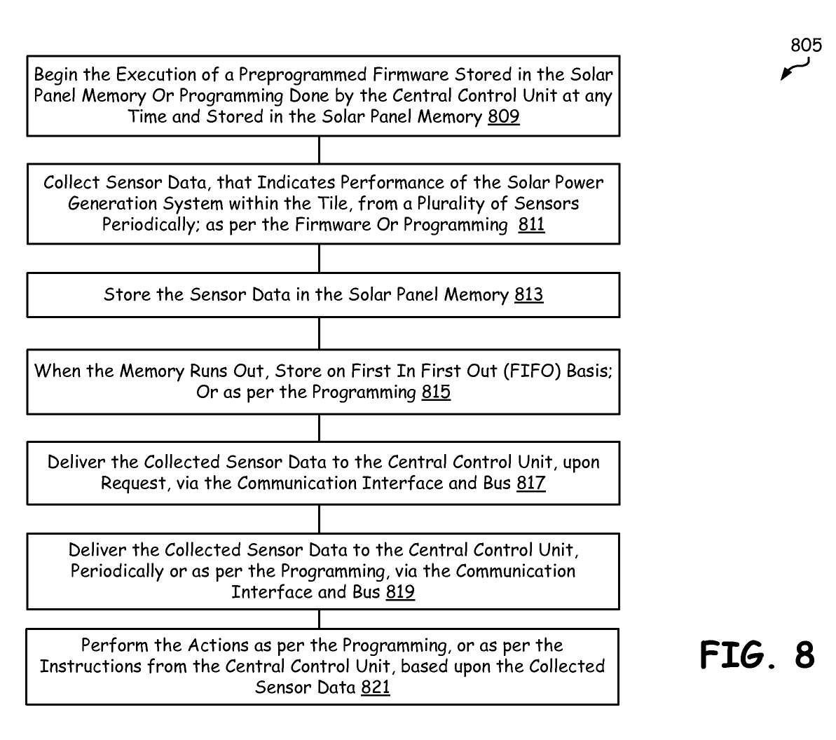

FIG. 8 is a flow diagram illustrating functionalities of the solar panel processing circuitry of the solar panel monitoring system of FIG. 1. The functionality begins at a block 809 when the solar panel processing circuitry begins to execute the preprogrammed firmware stored within the solar panel memory and/or program software stored within the central control unit and delivered to the solar panel memory as updates.

At a next block 811, the solar panel processing circuitry begins to collect sensor data that indicates performance of the solar power generation system within the tile from a plurality of sensors, one sensor at a time. The plurality of sensor may include current, voltage, temperature, light and solar panel tilt. At a next block 813, the solar panel processing circuitry stores the collected sensor data in the solar panel memory. At a next block 815, the solar panel processing circuitry continues to store the sensor data periodically (even if they are not used for any further processing by the solar panel processing circuitry or by the central control unit) in First-In-First-Out (FIFO) basis. Alternatively, the sensor data, upon reaching the storage limit of the memory, may deliver this data to the central control unit, if programmed so.

Alternatively, at a next block 817, the solar panel processing circuitry may perform tasks requested by the central control unit, at any time (such as when a remote server requests for the information, or a manual request is made at the central control unit), based upon collected sensor data, such as delivering the sensor data to the central control unit for further processing, via the communication interface and bus. At a next block 819, the solar panel processing circuitry may deliver the collected sensor data to the central control unit periodically or as per programming, via the communication interface and bus. The alternatives of the blocks 817 and 819 may depend upon the preinstalled software program in a system or remote server that controls the central control unit. The preinstalled software program allows the user many options such as when to collect and store sensor data, whether to collect periodically (and the period), what functions to perform based upon the sensor data and so forth.

At a final block 821, the solar panel processing circuitry performs actions based upon the collected sensor data (or periodic monitoring and maintenance actions that may not depend upon the collected sensor data) and as per the instructions received from the central control unit. These actions many involve controlling heater assembly, electrical rotational assembly, light module and overload and fire response module, and generating and sending maintenance reports to the central control unit.

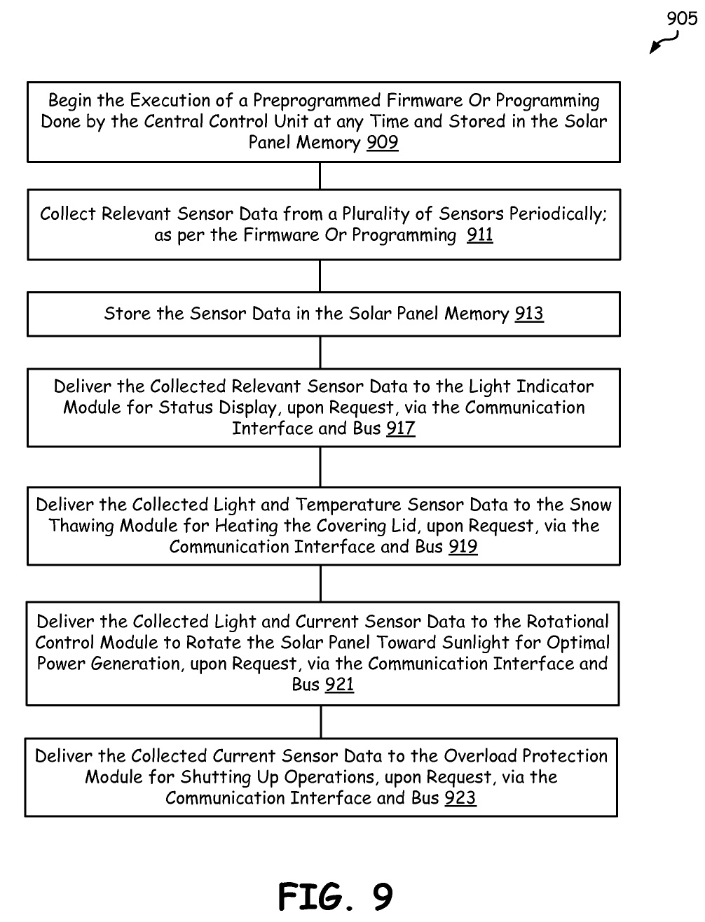

FIG. 9 is a flow diagram illustrating functionalities of the solar panel processing circuitry of the solar panel monitoring system of FIG. 1; wherein the solar panel processing circuitry controls the functionalities of over load protection, heater assembly and electrical rotational assembly. The functionality begins at a block 909 when the solar panel processing circuitry begins to execute the preprogrammed firmware stored within the solar panel memory and/or program firmware received from the central control unit and stored in the solar panel memory as updates, any time thereafter.

At a next block 911, the solar panel processing circuitry begins to collect relevant sensor data that indicates performance of the solar power generation system within the tile from each of the plurality of sensors, in rotational basis. At a next block 913, the solar panel processing circuitry stores the collected sensor data in the solar panel memory. At a next block 917, the solar panel processing circuitry processes the collected sensor data, such as temperature, light, humidity, current, tilt of the solar panel and so forth, for display and sends control signals to the lighting (indicator) module via communication interface and bus. The solar panel processing circuitry may send the data only upon the request from the central control unit, based upon the program options set by the user. The user may, for instance, set the options of status indication every weekend between 8 pm and 9 pm for routine checkup. Then, the solar panel processing circuitry sends the sensor data during that preset period, to the light module to display the status. The user may easily know that one of the modules is not functioning correctly, for instance, when, among plurality of tiles displaying green lights, one tile in the middle displays one of the red lights. Thus, this allows quick and easy identification of a problem and can be immediately attended to. For instance, the data from the current and voltage sensors may be processed by the solar panel processing circuitry to determine if any of the photovoltaic panels are not functioning properly. In addition, the lighting module may also receive the control signals, via the solar panel processing circuitry, from a remote server.

At a next block 919, the solar panel processing circuitry processes the collected light and temperature sensor data and sends control signals to the heating module, via the communication interface and bus. The control signal may simply be switching on and off the heating coils (with certain duty cycle) until the snow melts and enough solar light is available for generating power. Again, the user is able to set working of the snow thawing functionality at the central control unit, for instance, only during day times. In addition, the user may switch of this functionality altogether when not needed. Again, the heating module may also receive the control signals, via the solar panel processing circuitry, from a remote server.

At a next block 921, the solar panel processing circuitry processes the collected light, tilt and current sensor data and sends control signals to the electrical rotational assembly, via the communication interface and bus. The light indicator, heating module, electrical rotational assembly may tilt the solar panel within certain degree on all directions, and the control signal may depend upon the collected sensor data, the program instructions, control signals or instructions from the central control unit or a remote server.

At a final block 923, the solar panel processing circuitry processes the collected current sensor data (among other sensor data) and sends control signals to the overload protection and fire response module, via the communication interface and bus. The controlling of the overload protection and fire response module may simply involve sending control signals to switch off all functionalities of the roofing tile during emergency situation. Thus, the overload protection and fire response module may contain electrical or electronic relays that shut off all functionalities within the roofing tile.

The terms “circuit” and “circuitry” as used herein may refer to an independent circuit or to a portion of a multifunctional circuit that performs multiple underlying functions. For example, depending on the embodiment, processing circuitry may be implemented as a single chip processor or as a plurality of processing chips. Likewise, a first circuit and a second circuit may be combined in one embodiment into a single circuit or, in another embodiment, operate independently perhaps in separate chips. The term “chip”, as used herein, refers to an integrated circuit. Circuits and circuitry may comprise general or specific purpose hardware, or may comprise such hardware and associated software such as firmware or object code.

As one of ordinary skill in the art will appreciate, the terms “operably coupled” and “communicatively coupled,” as may be used herein, include direct coupling and indirect coupling via another component, element, circuit, or module where, for indirect coupling, the intervening component, element, circuit, or module does not modify the information of a signal but may adjust its current level, voltage level, and/or power level. As one of ordinary skill in the art will also appreciate, inferred coupling (i.e., where one element is coupled to another element by inference) includes direct and indirect coupling between two elements in the same manner as “operably coupled” and “communicatively coupled.”

The present invention has also been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claimed invention.

The present invention has been described above with the aid of functional building blocks illustrating the performance of certain significant functions. The boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality. To the extent used, the flow diagram block boundaries and sequence could have been defined otherwise and still perform the certain significant functionality. Such alternate definitions of both functional building blocks and flow diagram blocks and sequences are thus within the scope and spirit of the claimed invention.

One of average skill in the art will also recognize that the functional building blocks, and other illustrative blocks, modules and components herein, can be implemented as illustrated or by discrete components, application specific integrated circuits, processors executing appropriate software and the like or any combination thereof.

Moreover, although described in detail for purposes of clarity and understanding by way of the aforementioned embodiments, the present invention is not limited to such embodiments. It will be obvious to one of average skill in the art that various changes and modifications may be practiced within the spirit and scope of the invention, as limited only by the scope of the appended claims.

1. A solar panel of a solar power generation system comprising:
a housing;
a photovoltaic panel disposed within the housing;
a solar panel monitoring system comprising:
solar panel processing circuitry;
a solar panel communications interface;
solar panel memory; and
a solar panel sensor coupled to the photovoltaic panel; and
wherein the solar panel processing circuitry is operable to receive sensory data from the solar panel sensor regarding performance of the photovoltaic panel and to store the received sensory data in the solar panel memory; and
wherein the solar panel processing circuitry is operable to deliver the stored sensory data to a central control unit via the solar panel communications interface.

2. The solar panel of claim 1 further comprising:
a solar panel power bus coupled to the photovoltaic panel and disposed within the housing; and
a power interconnection disposed upon an external portion of the housing and electrically coupled to the solar panel power bus.

3. The solar panel tile of claim 2, wherein the solar panel power bus electrically couples to the solar panel monitoring system to power the solar panel monitoring system.

4. The solar panel of claim 1, wherein the solar panel communications interface supports wireless communications.

5. The solar panel of claim 1, wherein the solar panel communications interface supports wired communications via a wired communications port disposed on an external portion of the housing.

6. The solar panel of claim 1:
further comprising a temperature sensor disposed within the housing; and
wherein the solar panel processing circuitry is operable to receive temperature data from the temperature sensor, to store the temperature data within the solar panel memory, and to deliver the stored temperature data to a central control unit via the solar panel communications interface.

7. The solar panel of claim 1, wherein the solar panel monitoring system comprises a packaged integrated circuit electrically connected to the photovoltaic panel.

8. The solar panel of claim 1, wherein the processing circuitry delivers the stored sensory data to the central control unit via the solar panel communications interface upon demand from the central control unit.

9. The solar panel of claim 1, wherein the processing circuitry is operable to:
receive the sensory data over time;
determine that the photovoltaic panel requires maintenance based upon the sensory data received over time; and
deliver a maintenance request to the central control unit via the solar panel communications interface.

10. The solar panel of claim 1, wherein the solar panel sensor includes a current sensor.

11. The solar panel of claim 1, wherein the housing includes a transparent covering that protects the photovoltaic panel and the solar panel monitoring system.

12. The solar panel of claim 1, further comprising an interconnection structure disposed on an external portion of the housing for interconnection to at least one other solar panel.

13 The solar panel of claim 1, further comprising an interconnection structure disposed on an external portion of the housing for interconnection to a solar panel generation system interconnection structure.

14. The solar panel of claim 1, wherein the wherein the solar panel monitoring system further comprises a light sensor.

15. The solar panel of claim 1, further comprising an electrical rotational assembly upon which the photovoltaic panel mounts and that is operational to position the photovoltaic panel for enhanced power generation.

16. The solar panel of claim 1, further comprising a heater operable to heat a surface of the housing to melt accumulated snow.

17. A method for operating a solar panel of a solar power generation system that includes a housing, a photovoltaic panel disposed within the housing, and a solar panel monitoring system that includes solar panel processing circuitry, a solar panel communications interface, solar panel memory, and a solar panel sensor coupled to the photovoltaic panel, the method comprising:
receiving sensory data from the solar panel sensor regarding performance of the photovoltaic panel;
storing the received sensory data in the solar panel memory; and
delivering the stored sensory data to a central control unit via the solar panel communications interface.

18. The method of claim 17 further comprising coupling electrical power generated by the photovoltaic panel to an external portion of the housing via a solar panel power bus coupled to the photovoltaic panel and disposed within the housing.

19. The method of claim 18, further comprising powering the solar panel monitoring system via the solar panel power bus.

20. The method of claim 17, wherein delivering the stored sensory data to the central control unit via the solar panel communications interface includes wirelessly communicating via the solar panel communications interface.

21. The method of claim 17, wherein delivering the stored sensory data to the central control unit via the solar panel communications interface includes communicating via a wired communications port disposed on an external portion of the housing.

22. The method of claim 17, further comprising:
receiving temperature data regarding temperatures within the housing via a temperature sensor;
storing the temperature data within the solar panel memory; and
delivering the stored temperature data to a central control unit via the solar panel communications interface.

23. The method of claim 17, wherein delivering the stored sensory data to the central control unit via the solar panel communications interface is performed in response to a request received from the central control unit.

24. The method of claim 17, further comprising:
receiving the sensory data over time;
determining that the photovoltaic panel requires maintenance based upon the sensory data received over time; and
delivering a maintenance request to the central control unit via the solar panel communications interface.

25. The method of claim 17, wherein receiving sensory data from the solar panel sensor regarding performance of the photovoltaic panel includes receiving current generation data regarding the photovoltaic panel.

26. The method of claim 17, further comprising positioning the photovoltaic panel for enhanced power generation.

27. The method of claim 17, further comprising heating at least one of the photovoltaic panel and the housing to melt accumulated snow.
